(19) United States
(12) Patent Application Publication
(10) Pub. No.: US 2019/0267491 A1
(43) Pub. Date: Aug. 29, 2019

(54) WAVY FET STRUCTURE

(71) Applicant: Bruckewell Technology Corp., Ltd., Hsinchu County (TW)

(72) Inventors: Shih-Hao Yeh, Hsinchu County (TW); Lo Verde Domenico, Hsinchu County (TW); Ronsisvalle Cesare, Hsinchu County (TW)

(21) Appl. No.: 15/905,844

(22) Filed: Feb. 27, 2018

(51) Int. Cl. H01L 29/78; H01L 29/16; H01L 29/49; H01L 29/08

(52) U.S. Cl. CPC H01L 29/7851; H01L 29/1608; H01L 2029/7857; H01L 29/0847; H01L 29/4933

(57) ABSTRACT

A wavy FET structure includes a semiconductor substrate having a first conductive type, a source doped region and a drain doped region both having a second conductive type, a gate structure, and first and second metal layers. The semiconductor substrate includes a surface and a fin portion formed on the surface. The fin portion has first and second ends along its length direction. The source doped region is formed on the first end and on a first partial region at a lower portion of the first end and contacting the surface. The drain doped region is formed on the second end and on a second partial region at a lower portion of the second end and contacting the surface. The gate structure covers the fin portion. The first metal layer contacts and covers the source doped region. The second metal layer contacts and covers the drain doped region.

### FIELD OF INVENTION

The instant disclosure relates a transistor structure, and in particular, to a wavy FET structure.

### BACKGROUND OF THE INVENTION

As compared with an integrated circuits (IC) in 1960s, the time integrated circuits (IC) are developed, the component density of a nowadays IC increases greatly. Along with the increase of the component density of the IC, the size of the components of the IC also reduces continuously. Taking the FET (field-effect transistor) as an example, the length of the channel between the source and the drain is required to be made by the 65 nm technology. In order to have a higher component density of the IC, a better performance of the component, and a lower manufacturing cost, the manufacturing and design of the circuit become challenging. Therefore, components produced by a three-dimensional design are developed to replace the conventional planar components.

For example, a fin field-effect transistor (FinFET) is a three-dimensional metal-oxide-semiconductor (MOS) transistor and developed by the conventional field-effect transistor (FET). In a conventional FET structure, the channel between the source and the drain can only be controlled by the gate at one side of the substrate. Thus, the conventional FET is a planar structure. Conversely, the gate, the drain, and the source of a FinFET form a three-dimensional fish-fin structure, the gate may further cover the lateral surface of the channel to increase the perimeter of the channel. Therefore, how to increase the volume of the channel of a FinFET becomes an issue. Moreover, in a conventional ET structure, the FinFET is formed on a Silicon On Insulator (SOI) substrate, yet the SOI substrate is expensive, resulting in the increase of manufacturing cost.

### SUMMARY OF THE INVENTION

In view of these, a wavy field-effect transistor structure is provided.

In one embodiment, the wavy FET structure comprises a semiconductor substrate, a source doped region, a drain doped region, a gate structure, a first metal layer, and a second metal layer. The semiconductor substrate has a first conductive type and comprises a surface and a fin portion formed on the surface. The fin portion has a first end and a second end along a length direction thereof. The source doped region has a second conductive type. The source doped region is formed on the first end of the fin portion, and is formed on a first partial region which is at a lower portion of the first end and in contact with the surface, and is formed at two sides of the first partial region along a lateral direction which is perpendicular to the length direction. The drain doped region has the second conductive type. The drain doped region is formed on the second end of the fin portion, and is formed on a second partial region which is at a lower portion of the second end and in contact with the surface, and is formed at two sides of the second partial region along the lateral direction. The gate structure covers the fin portion and a portion of the surface between the first partial region and the second partial region. The first metal layer contacts and covers the source doped region. The second metal layer contacts and covers the drain doped region.

Based on the above, according to the embodiment of the wavy FET structure, the source doped region and the drain doped region are formed on the surface of the semiconductor substrate, so that the perimeter of the channel can increase, thereby increasing the overall volume of the channel.

### BRIEF DESCRIPTION OF THE DRAWINGS

The disclosure will become more fully understood from the detailed description given herein below for illustration only, and thus not limitative of the disclosure, wherein:

FIG. 1 illustrates a right side view of an exemplary embodiment of a wavy FET structure according to the instant disclosure;

FIG. 2 illustrates a left side view of the wavy FET structure;

FIG. 3 illustrates a schematic view of an embodiment of a semiconductor substrate of the wavy FET structure shown in FIGS. 1 and 2;

FIG. 4 illustrates a cross-sectional view of the semiconductor substrate along the line 4-4 shown in FIG. 3;

FIG. 5 illustrates a right side view of an embodiment of the semiconductor substrate, a source doped region, and a drain doped region of the wavy FET structure shown in FIGS. 1 and 2;

FIG. 6 illustrates a left side view of an embodiment of the semiconductor substrate, the source doped region, and the drain doped region of the wavy FET structure shown in FIGS. 1 and 2;

FIG. 7 illustrates a cross-sectional view of one embodiment of a gate structure of the wavy FET structure along the line 7-7 shown in FIG. 1; and

FIG. 8 illustrates a cross-sectional view of another embodiment of a gate structure of the wavy FET structure along the line 7-7 shown in FIG. 1.

### DETAILED DESCRIPTION OF THE INVENTION

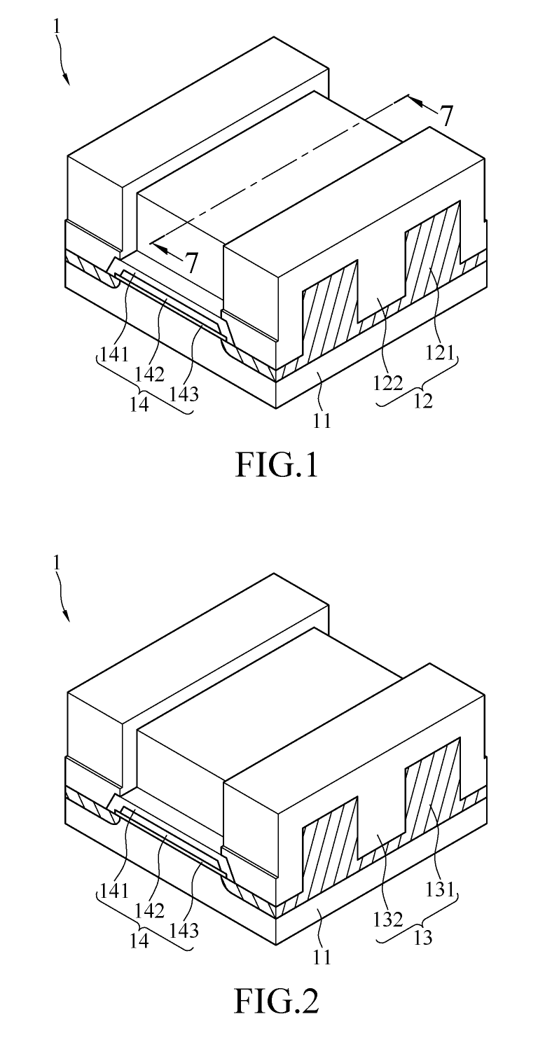

FIGS. 1 and 2 respectively illustrate right and left side views of an exemplary embodiment of a wavy field-effect transistor (FET) structure 1. As shown in FIGS. 1 and 2, the wavy FET structure 1 comprises a semiconductor substrate 11 and a source structure 12, a drain structure 13, and a gate structure 14 that are formed on the semiconductor substrate 11. The semiconductor substrate 11 has a first conductive type. The source structure 12 comprises a source doped region 121 having a second conductive type and a first metal layer 122 covering the source doped region 121. The drain structure 13 comprises a drain doped region 131 having the second conductive type and a second metal layer 132 covering the drain doped region 131. The gate structure 14 is located between the source structure 12 and the drain structure 13.

In some embodiments, the first conductive type and the second conductive type may be, respectively, P type and N type, and the semiconductor substrate 11 is made of silicon. Therefore, the semiconductor substrate 11 may comprise P type silicon, and the source doped region 121 and the drain doped region 131 may comprise heavily doped N type silicon. In some embodiments, the first conductive type and the second conductive type may be, respectively, N type and P type. That is, the semiconductor substrate 11 may comprise N type silicon, and the source doped region 121 and the drain doped region 131 may comprise heavily doped P type silicon. In some embodiments, the semiconductor substrate 11 may comprise silicon carbide (SiC).

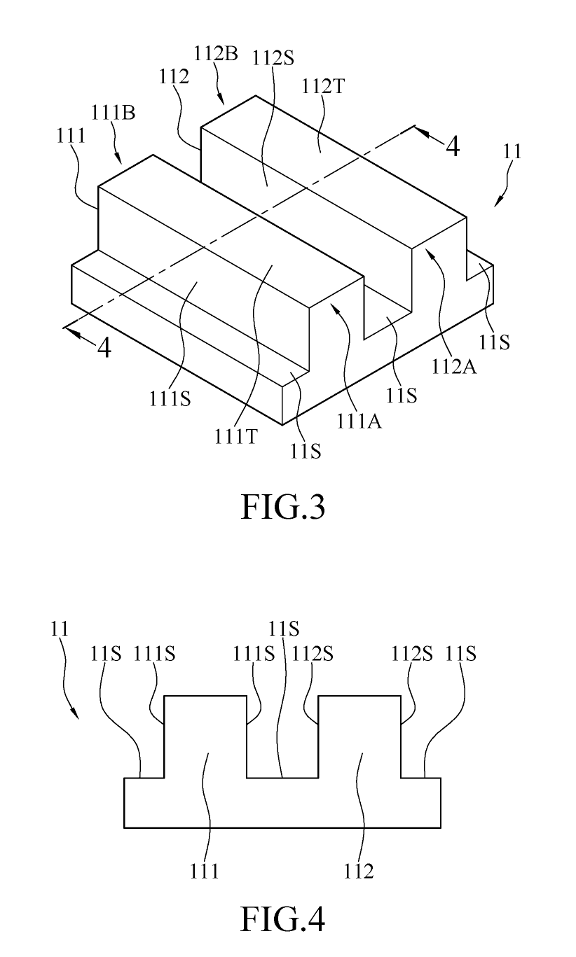

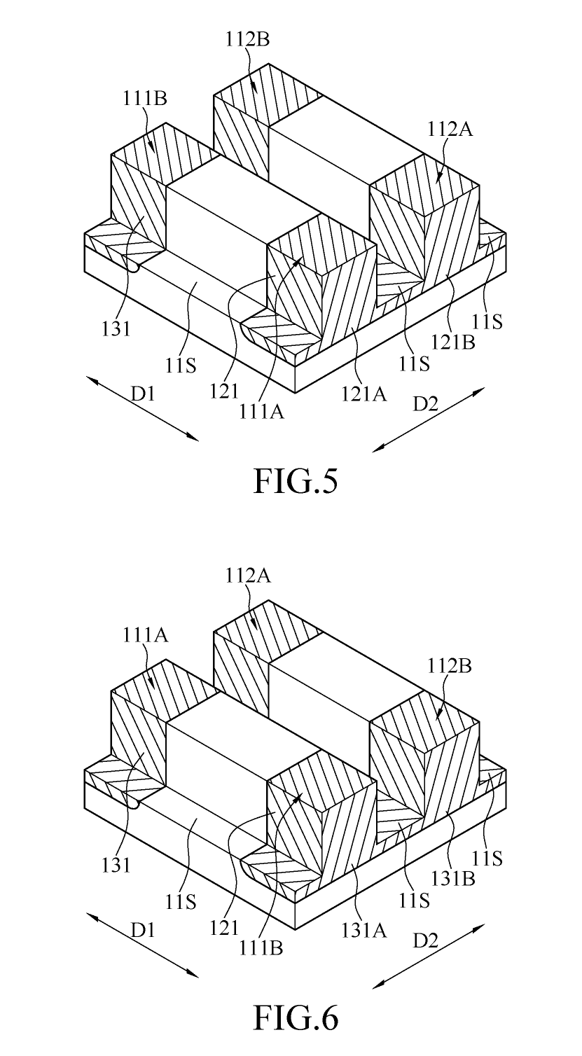

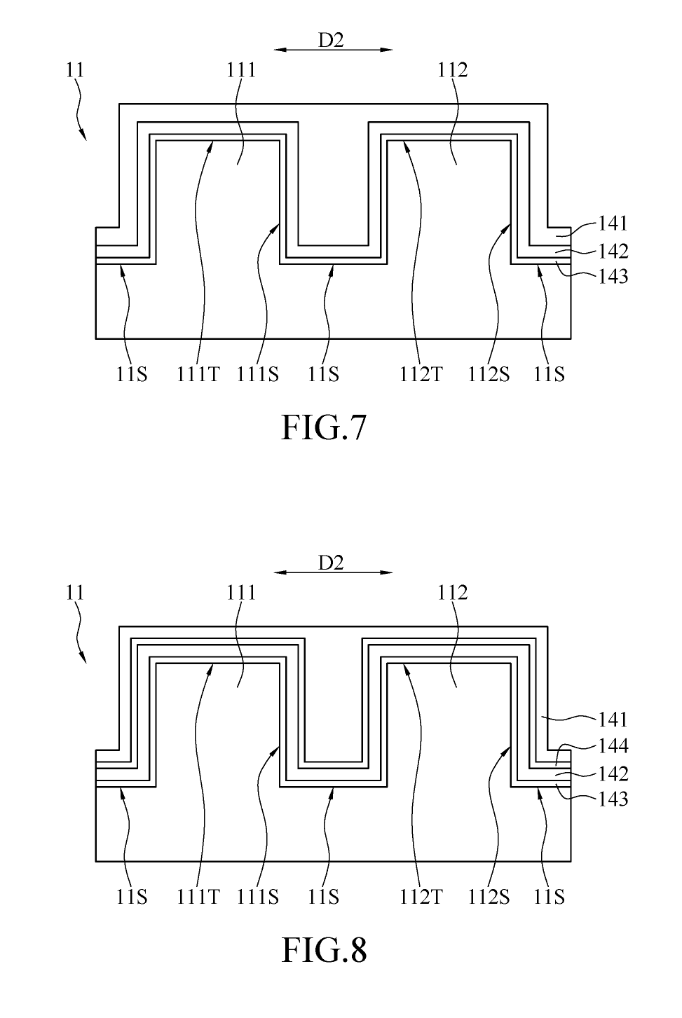

FIG. 3 illustrates a schematic view of an embodiment of the semiconductor substrate 11 of the wavy FET structure 1 shown in FIGS. 1 and 2. FIG. 4 illustrates a cross-sectional view of the semiconductor substrate 11 along the line B-B shown in FIG. 3. FIGS. 5 and 6 respectively illustrate right and left side views of an embodiment of the semiconductor substrate 11, the source doped region 121, and the drain doped region 131 of the wavy FET structure 1 shown in FIGS. 1 and 2. FIG. 7 illustrates a cross-sectional view of one embodiment of the gate structure 14 of the wavy FET structure 1 along the line A-A shown in FIG. 1. Please refer to FIGS. 3 to 7, the semiconductor substrate 11 has a surface 11S and a fin portion 111 formed on the surface 11S. The fin portion 111 has a first end 111A and a second end 111B along a length direction D1 thereof, and the fin portion 111 has a middle portion between the first end 111A and the second end 111B. As shown in FIG. 5, the source doped region 121 is formed on the first end 111A of the fin portion 111 and a partial region (for convenience, called first partial region 121A) which is at a lower portion of the first end 111A and in contact with the surface 11S. As shown in FIG. 6, the drain doped region 131 is formed on the second end 111B of the fin portion 111 and a partial region (for convenience, called second partial region 131A) which is at a lower portion of the second end 111B and in contact with the surface 11S.

Further, as shown in FIG. 7, the gate structure 14 covers two lateral surfaces 111S and a top surface 111T of the middle portion of the fin portion 111. In the case that the first conductive type is P type and the second conductive type is N type, when a sufficient positive voltage is applied to the gate structure 14 externally, the space between the first end 111A and the second end 111B of the fin portion 111 (FIG. 3) is full of electrons, so that the three-dimensional space among the lateral surfaces 111S, the top surface 111T, and the surface 11S is formed as a channel. In addition, the space between the first partial region 121A and the second partial region 131A that are below the surface 11S is also full of electrons and formed as another channel (FIG. 5, 6). Accordingly, the current may flow from a portion of the source doped region 121 above the surface 11S to the drain doped region 131, or may flow from a portion of the source doped region 121 below the surface 11S (i.e., the first partial region 121A) to the drain doped region 131. Therefore, as compared with that of a conventional wavy FET structure, the semiconductor substrate 11 excludes an insulator layer; moreover, the source doped region 121 and the drain doped region 131 are formed on the surface 11S of the semiconductor substrate 11. Accordingly, the manufacturing cost can be reduced, and the depth of the channel can be increased in a limited space, so that the overall volume of the channel can be increased as well.

Furthermore, as shown in FIG. 5, a lateral direction D2 is perpendicular to the length direction D1 of the fin portion 111. In some embodiments, the source doped region 121 is also formed on two sides of the first partial region 121A along the lateral direction D2; namely, the source doped region 121 also exists on the surface 11S at two sides of the first end 111A of the fin portion 111, and the source doped region 121 is of an inverse T shape which has a thinner upper portion and a wider lower portion. Likewise, as shown in FIG. 6, the drain doped region 131 is also formed on two sides of the second partial region 131A along the lateral direction D2; namely, the drain doped region 131 also exists on the surface 11S at two sides of the second end 111B of the fin portion 111, and the drain doped region 131 is of an inverse T shape which has a thinner upper portion and a wider lower portion.

Moreover, as shown in FIGS. 6 and 7, the gate structure 14 may be extending from the side surfaces of the fin portion 111 along the lateral direction D2, and the gate structure 14 further covers the surface 11S between the source doped region 121 at the two sides of the first partial region 121A and the drain doped region 131 at the two sides of the second partial region 131A. Accordingly, in the case that the first conductive type is P type and the second conductive type is N type, when a sufficient positive voltage is externally applied to the gate structure 14 on the surface 11S at two sides of the fin portion 111, the space between the source doped region 121 at the two sides of the first partial region 121A and the drain doped region 131 at the two sides of the second partial region 131A is also full of electrons to be form a channel. Therefore, the current may flow on the surface 11S, from the source doped region 121 at the two sides of the first partial region 121A to the drain doped region 131 at the two sides of the second partial region 131A. Therefore, as compared with that of a conventional wavy FET structure, the surface 11S of the semiconductor substrate 11 also comprises the source doped region 121 and the drain doped region 131. Accordingly, the overall volume of the channel is increased, thereby further improving the performance of the wavy FET structure 1.

In some embodiments, as shown in FIG. 7, the gate structure 14 may be a multi-layer structure. The gate structure 14 comprises a gate oxide layer 143, a poly gate layer 142, and an insulator gate layer 141. The gate oxide layer 143 may be in contact with and cover the two lateral surfaces 111S and the top surface 111T of the fin portion 111 as well as the surface 11S at the two sides of the fin portion 111. The poly gate layer 142 is in contact with and covers the gate oxide layer 143. The insulator gate layer 141 is in contact with and covers the poly gate layer 142. In some embodiments, as shown in FIG. 8, the gate structure 14 may further comprises a silicide layer 144 being formed between the poly gate layer 142 and the insulator gate layer 141. The silicide layer 144 may comprise cobalt silicide (e.g. CoSi₂). The silicide layer 144 is in contact with and covers the poly gate layer 142 to reduce the resistance of the gate structure 14. In some embodiments, in order to improve the conductivity of the channel, the gate oxide layer 143 can be replaced with a high-K dielectric layer (i.e. the poly gate layer 142 is in contact with and covers the high-K dielectric layer, and the high-K dielectric layer is in contact with and covers the semiconductor substrate 11).

In some embodiments, as shown in FIGS. 1 and 2, the gate structure 14 on the fin portion 111 is in contact with the first metal layer 122 and the second metal layer 132, and the gate structure 14 on the surface 11S is also in contact with the first metal layer 122 and the second metal layer 132. In this embodiment, the wavy FET structure 1 is devoid of a drift layer, so that a resistance caused by drift layer-, between the source structure 12 and the drain structure 13 can be eliminated. For improving the conductivity of the channel in such embodiment, the gate structure 14 may comprise high dielectric constant (high-k) material, so that the conductivity of the channel can greatly increase and not to be affected by the resistance caused by the drift layer.

In some embodiments, the semiconductor substrate 11 may further comprise another fin portion (for convenience, called fin portion 112), so that another FET is formed on the surface 11S. As shown in FIGS. 3 and 4, the fin portion 112 is aligned along the lateral direction D2 and parallel to the fin portion 111. The fin portion 112 has the same length direction D1 as the fin portion 111. The fin portion 112 has a first end 112A and a second end 112B along the length direction D1, and the fin portion 112 has a middle portion between the first end 112A and the second end 112B. In addition, the fin portion 112 has two lateral surfaces 112S and a top surface 112T. The lateral surface 112S at the first end 112A of the fin portion 112 faces the lateral surface 111S at the first end 111A of the fin portion 111, and the lateral surface 112S at the second end 112B of the fin portion 112 faces the lateral surface 111S at the second end 111B of the fin portion 111. As shown in FIG. 5, the source doped region 121 is further formed on the first end 112A of the fin portion 112, a partial region (for convenience, called third partial region 121B) which is at a lower portion of the first end 112A and in contact with the surface 11S, and portions of the fin portion 112 at two sides of the third partial region 121B. Likewise, as shown in FIG. 6, the drain doped region 131 is further formed on the second end 112B of the fin portion 112, a partial region (for convenience, called fourth partial region 131B) which is at a lower portion of the second end 112B and in contact with the surface 11S, and portions of the fin portion 112 at two sides of the fourth partial region 131B. Accordingly, the space between the third partial region 121B and the fourth partial region 131B can be full of electrons to form a channel, and the space between the source doped region 121 at the two sides of the third partial region 121B and the drain doped region 131 at the two sides of the fourth partial region 131B can be full of electrons to form a channel.

It is understood that, as shown in FIGS. 1, 2, and 7, the gate structure 14 is extending from the fin portion 111 to the fin portion 112, and the gate structure 14 further covers the two lateral surfaces 112S of the middle portion of the fin portion 112, the top surface 112T of the middle portion of the fin portion 112, and the surface 11S between the source doped region 121 at the two sides of the third partial region 121B and the drain doped region 131 at the two sides of the fourth partial region 131B. The first metal layer 122 is extending from the first end 111A of the fin portion 111 to the first end 112A of the fin portion 112 to cover the first end 112A and the source doped region 121 at two sides of the first end 112A. The second metal layer 132 is extending from the second end 111B of the fin portion 111 to the second end 112B of the fin portion 112 to cover the second end 112B and the drain doped region 131 at two sides of the second end 112B. In this embodiment, the two FETs on the semiconductor substrate 11 have a combined source structure 12, a combined drain structure 13, and a combined gate structure 14. Therefore, when the wavy FET structure 1 is packaging, the combined source structure 12, the combined drain structure 13, and the combined gate structure 14 may be respectively provided with a contact for reducing the area for wiring, so that the packaging volume of the wavy FET structure 1 can be reduced. While in FIGS. 1 and 2, the wavy FET structure 1 is provided with two FETs, but embodiments are not limited thereto; the number of the fin portion can be changed based on different needs or applications.

In some embodiments, for manufacturing the wavy FET structure shown in FIG. 1, firstly, by lithography, a plurality of troughs is formed on the surface of the semiconductor substrate 11 for forming a plurality of fin portions (e.g., the fin portions 111, 112); and then, by diffusion or ion implantation, dopants are doped to the first ends 111A, 112A of the fin portions 111, 112, portions below the first ends 111A, 112A, and portions at two sides of the first end 111A (and at two sides of the first end 112A) to form the source doped region 121; similarly, by the same procedure, dopants are doped to the second ends 111B, 112B of the fin portions 111, 112, portions below the second ends 111B, 112B, and portions at two sides of the second end 111B (and at two sides of the second end 112B) to form the drain doped region 131; lastly, several deposition processes are applied to form the first metal layer 122, the second metal layer 132, and the gate structure 14.

Based on the above, according to the embodiment of the wavy FET structure, the source doped region and the drain doped region are formed on the surface of the semiconductor substrate, so that the width and the depth of the channel can increase, thereby increasing the overall volume of the channel. In addition, the semiconductor substrate is in contact with the source structure so that the base is electrically connected to the source for preventing the occurrence of body effect.

While the instant disclosure has been described by the way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A wavy FET structure, comprising:
a semiconductor substrate having a first conductive type, wherein the semiconductor substrate comprises a surface and a fin portion formed on the surface, wherein the fin portion has a first end and a second end along a length direction thereof;
a source doped region having a second conductive type, wherein the source doped region is formed on the first end of the fin portion, and is formed on a first partial region which is at a lower portion of the first end and in contact with the surface, and is formed at two sides of the first partial region along a lateral direction which is perpendicular to the length direction;
a drain doped region having the second conductive type, wherein the drain doped region is formed on the second end of the fin portion, and is formed on a second partial region which is at a lower portion of the second end and in contact with the surface, and is formed at two sides of the second partial region along the lateral direction;
a gate structure covering the fin portion and a portion of the surface between the first partial region and the second partial region;
a first metal layer contacting and covering the source doped region; and
a second metal layer contacting and covering the drain doped region;
wherein the source doped region respectively formed at two sides of the first partial region are connected to each other under the surface, and the drain doped region respectively formed at two sides of the second partial region are connected to each other each other under the surface.

2. The wavy FET structure according to claim 1, wherein the semiconductor substrate further comprises a second fin portion formed on the surface, wherein the second fin portion has a first end and a second end along a length direction thereof, the source doped region is further formed on the first end of the second fin portion and on a third partial region which is at a lower portion of the first end of the second fin portion and in contact with the surface, the drain doped region is further formed on the second end of the second fin portion and on a fourth partial region which is at a lower portion of the second end of the second fin portion and in contact with the surface, and the gate structure further covers the second fin portion.

3. The wavy FET structure according to claim 2, wherein the source doped region is further formed at two sides of the third partial region along a lateral direction which is perpendicular to the length direction, wherein the drain doped region is further formed on a lateral direction of the fourth partial region which is perpendicular to the length direction, and wherein the gate structure further covers a portion of the surface between the third partial region and the fourth partial region.

4. The wavy FET structure according to claim 1, wherein the gate structure is in contact with the first metal layer and the second metal layer.

5. The wavy FET structure according to claim 1, wherein the semiconductor substrate excludes an insulator layer.

6. The wavy FET structure according to claim 1, wherein the semiconductor substrate comprises carbon or silicon carbide.

7. The wavy FET structure according to claim 1, wherein the gate structure comprises an insulator gate layer, a poly gate layer, and a gate oxide layer, the insulator gate layer covers the poly gate layer, the poly gate layer covers the gate oxide layer.

8. The wavy FET structure according to claim 7, wherein the gate structure further comprises a silicide layer, the silicide layer is formed between the insulator gate layer and the poly gate layer.

9. The wavy FET structure according to claim 1, wherein the gate structure comprises an insulator gate layer, a poly gate layer, and a high-K dielectric layer, the insulator gate layer covers the poly gate layer, the poly gate layer covers the high-K dielectric layer.
